(19) United States
(12) Patent Application Publication
(10) Pub. No.: US 2024/0047606 A1
(43) Pub. Date: Feb. 8, 2024

(54) WAFER LEVEL FABRICATION FOR MULTIPLE CHIP LIGHT-EMITTING DEVICES

(71) Applicant: CreeLED, Inc., Durham, NC (US)

(72) Inventors: Michael Check, Holly Springs, NC (US); Steven Wuester, Wake Forest, NC (US); Thomas Celano, Cary, NC (US); David Suich, Durham, NC (US); Colin Blakely, Raleigh, NC (US); Jesse Reiherzer, Raleigh, NC (US)

(21) Appl. No.: 17/817,186

(22) Filed: Aug. 3, 2022

(51) Int. Cl. H01L 33/00; H01L 33/62

(52) U.S. Cl. CPC H01L 33/0095; H01L 33/0093; H01L 33/62; H01L 2933/005

(57) ABSTRACT

Light-emitting devices and more particularly wafer level fabrication for multiple chip light-emitting devices is disclosed. Light-emitting devices include certain LED package structures, such as LED chips, submounts, and electrical connections that are formed by wafer level fabrication before individual light-emitting devices are separated. Methods include joining LED wafers with multiple LED chips formed thereon to submount wafers that include corresponding metallization patterns, followed by separating individual light-emitting devices. Each light-emitting device includes arrays of LED chips that are already bonded to a submount with electrical connections. The arrays of LED chips may be electrically coupled in a variety of electrical configurations based on arrangements of the metallization patterns.

### FIELD OF THE DISCLOSURE

The present disclosure relates to light-emitting devices and more particularly to wafer level fabrication for multiple chip light-emitting devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, indium phosphide, aluminum nitride, gallium arsenide-based materials, and/or from organic semiconductor materials.

LED packages have been developed that can provide mechanical support, electrical connections, and encapsulation for LED emitters. Multiple LED chip packages have also been developed that include an array of LED chips arranged closely together within a package. In such applications, there can be challenges in producing high quality light with desired emission characteristics while also providing suitable packaging arrangements that accommodate the presence of multiple LED chips within a single LED package.

The art continues to seek improved LEDs and solid-state lighting devices having desirable illumination characteristics capable of overcoming challenges associated with conventional lighting devices.

### SUMMARY

The present disclosure relates to light-emitting devices and more particularly to wafer level fabrication for multiple chip light-emitting devices. Such light-emitting devices may include certain light-emitting diode (LED) package structures, such as LED chips, submounts, and electrical connections that are formed by wafer level fabrication before individual light-emitting devices are separated. Methods include joining LED wafers with multiple LED chips formed thereon to submount wafers that include corresponding metallization patterns, followed by separating individual light-emitting devices. Each light-emitting device includes arrays of LED chips that are already bonded to a submount with electrical connections. The arrays of LED chips may be electrically coupled in a variety of electrical configurations based on the arrangements of the metallization patterns.

In one aspect, a method comprises: providing an LED wafer comprising a plurality of LED chips, each LED chip of the plurality of LED chips comprising an anode contact and a cathode contact; providing a submount wafer comprising a first metallization pattern on a frontside of the submount wafer and a second metallization pattern on a backside of the submount wafer, the second metallization pattern being electrically coupled to the first metallization pattern; bonding the LED wafer to the frontside of the submount wafer such that the anode contact and the cathode contact of each LED chip are electrically coupled to the first metallization pattern; and singulating the LED wafer and the submount wafer to form a plurality of light-emitting devices, each light-emitting device of the plurality of light-emitting devices comprising a substrate formed from the LED wafer, an array of LED chips of the plurality of LED chips, and a submount formed from the submount wafer. In certain embodiments, the LED wafer comprises a substrate structure that is subdivided to form each substrate of the plurality of light-emitting devices, and the submount wafer comprises a submount structure that is subdivided to form each submount of the plurality of light-emitting devices. In certain embodiments, the substrate structure comprises a sapphire wafer on which the plurality of LED chips are formed. In certain embodiments, the submount structure comprises aluminum oxide or aluminum nitride.

In certain embodiments, the first metallization pattern comprises a separate pair of an anode metal trace and a cathode metal trace that are respectively bonded to the anode contact and the cathode contact of each LED chip of the plurality of LED chips. In certain embodiments, the second metallization pattern comprises a first metal trace that forms an anode mounting pad, a second metal trace that forms a cathode mounting pad, and a third metal trace that forms part of an electrically conductive path between the first metal trace and the second metal trace.

In certain embodiments, a spacing between next adjacent LED chips of the plurality of LED chips is less than or equal to 40 microns (μm). In certain embodiments, the spacing is in a range from 10 μm to 40 μm. In certain embodiments, the plurality of LED chips are subdivided from a common epitaxial LED structure. In certain embodiments, bonding the LED wafer to the frontside of the submount wafer comprises thermocompression bonding, eutectic bonding, transient liquid phase bonding, bump bonding, or solder paste bonding the anode contact and the cathode contact to the first metallization pattern.

In certain embodiments, bonding the LED wafer to the frontside of the submount wafer comprises forming a ceramic bond between the LED wafer and the submount wafer. The method may further comprise forming an underfill material in gaps between the LED wafer and the submount wafer. In certain embodiments, the array of LED chips are electrically coupled in series, in parallel, or in series and parallel. In certain embodiments, the second metallization pattern comprises: a first pattern of metal traces configured to electrically couple the array of LED chips for a first light-emitting device of the plurality of light-emitting devices with a first electrical configuration; and a second pattern of metal traces configured to electrically couple the array of LED chips for a second light-emitting device of the plurality of light-emitting devices with a second electrical configuration. In certain embodiments, the submount structure comprises a multiple layer ceramic structure.

In another aspect, a method comprises: providing an LED wafer comprising a plurality of LED chips on a substrate structure; forming a first underfill material on the LED wafer; providing a submount wafer comprising a first metallization pattern on a frontside of the submount wafer and a second metallization pattern on a backside of the submount wafer, the second metallization pattern being electrically coupled to the first metallization pattern; bonding the LED wafer to the frontside of the submount wafer such that the plurality of LED chips are electrically coupled to the first metallization pattern; and singulating the LED wafer and the submount wafer to form a plurality of light-emitting devices, each light-emitting device of the plurality of light-emitting devices comprising an array of LED chips of the plurality of LED chips and a submount formed from the submount wafer.

In certain embodiments, the LED wafer comprises a plurality of streets that define boundaries of each LED chip of the plurality of LED chips and the first underfill material is arranged to fill portions of the plurality of streets. In certain embodiments, the first underfill material comprises light-reflective materials configured to reflect or redirect light from the plurality of LED chips. In certain embodiments, the first underfill material is formed on the LED wafer after the LED wafer is mounted to the submount wafer. In certain embodiments, the first underfill material is formed on the LED wafer before the LED wafer is mounted to the submount wafer. The method may further comprise forming a second underfill material on the submount wafer before the LED wafer is mounted to the submount wafer. In certain embodiments, the first underfill material and the second underfill material form a ceramic bond between the LED wafer and the submount wafer. In certain embodiments, the array of LED chips are electrically coupled in series, in parallel, or in series and parallel.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is top view of a light-emitting diode (LED) wafer with an exploded portion illustrating a view of LED chips formed thereon.

FIG. 1B is a top view of a submount wafer with an exploded portion illustrating a view of a first metallization pattern formed thereon.

FIG. 2A is a cross-sectional view at a fabrication step for forming multiple light-emitting devices where the LED wafer of FIG. 1A is positioned for mounting to the submount wafer of FIG. 1B.

FIG. 2B is a cross-sectional view at a subsequent fabrication step to FIG. 2A where the LED wafer is bonded to the submount wafer.

FIG. 2C is a cross-sectional view at a subsequent fabrication step to FIG. 2B where the light-emitting devices have been separated from one another along the vertical dashed lines of FIG. 2B.

FIG. 3A is a cross-sectional view at a fabrication step for forming multiple light-emitting devices that is similar to the fabrication step illustrated in FIG. 2A and further includes one or more underfill materials.

FIG. 3B is a cross-sectional view at a subsequent fabrication step to FIG. 3A for forming the multiple light-emitting devices that is similar to the fabrication step illustrated in FIG. 2B.

FIG. 3C is a cross-sectional view at a subsequent fabrication step to FIG. 3B for forming the multiple light-emitting devices that is similar to the fabrication step illustrated in FIG. 2C.

FIG. 4A is a view of a first side of the submount wafer of FIGS. 1B to 3C where superimposed vertical and horizontal dashed lines form a grid of sixteen different device regions, each of which includes four pairs of frontside metal traces.

FIG. 4B is a view of the submount wafer of FIG. 4A from the same orientation as FIG. 4A, except with the frontside metal traces removed and the submount structure illustrated as transparent to provide views of backside metal traces.

FIG. 4C is a view from a portion of FIG. 4A illustrating four pairs of the frontside metal traces for a single device region.

FIG. 4D is a view from a portion FIG. 4B illustrating the backside metal traces along with the locations of vias.

FIG. 4E is a view of the submount wafer where the image of FIG. 4C with the frontside metal traces is overlaid on the image of FIG. 4D with alignment according to the vias.

FIG. 4F illustrates an equivalent circuit for LED chips that may be subsequently mounted to the frontside metal traces of FIG. 4E.

FIG. 5A is a view of the first side of a submount wafer that is similar to FIG. 4C, except locations of one or more of the vias relative to each of the frontside metal traces are different to accommodate parallel coupling as described below.

FIG. 5B is a view of the backside of the submount wafer from FIG. 5A.

FIG. 5C is a view of the submount wafer where the image of FIG. 5A with the frontside metal traces is overlaid on the image of FIG. 5B with alignment according to the vias.

FIG. 5D illustrates an equivalent circuit for LED chips that may be subsequently mounted to the frontside metal traces of FIG. 5C.

FIG. 6A is a view of the first side of a submount wafer that is similar to FIG. 4C, except locations of one or more of the vias relative to each of the frontside metal traces are different to accommodate parallel and series configurations.

FIG. 6B is a view of the backside of the submount wafer from FIG. 6A.

FIG. 6C is a view of the submount wafer where the image of FIG. 6A with the frontside metal traces is overlaid on the image of FIG. 6B with alignment according to the vias.

FIG. 6D illustrates an equivalent circuit for LED chips that may be subsequently mounted to the frontside metal traces of FIG. 6C.

FIG. 7A is a frontside view of a portion of a submount wafer that is similar to the view provided by FIG. 4C, except the submount wafer includes a multiple layer structure with vias and interconnections for routing electrically conductive paths.

FIG. 7B is a backside view of the submount wafer of FIG. 7A, illustrating two backside metal traces that form anode and cathode mounting pads for the corresponding light-emitting device.

FIG. 7C is a cross-section taken along the sectional line 7C-7C of FIG. 7A.

FIG. 7D is a cross-section taken along the sectional line 7D-7D of FIG. 7A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting devices and more particularly to wafer level fabrication for multiple chip light-emitting devices. Such light-emitting devices may include certain light-emitting diode (LED) package structures, such as LED chips, submounts, and electrical connections that are formed by wafer level fabrication before individual light-emitting devices are separated. Methods include joining LED wafers with multiple LED chips formed thereon to submount wafers that include corresponding metallization patterns, followed by separating individual light-emitting devices. Each light-emitting device includes arrays of LED chips that are already bonded to a submount with electrical connections. The arrays of LED chips may be electrically coupled in a variety of electrical configurations based on the arrangements of the metallization patterns.

Light-emitting devices as disclosed herein may include multiple LED chips with certain LED package structures, such as submounts and electrical connections, that are joined together by wafer level fabrication. By joining multiple LED chips with a submount that includes electrical connections at the wafer level, individual groups of LED chips that are already bonded to a submount with electrical connections may be singulated to form multiple LED chip light-emitting devices.

Before delving into specific details of various aspects of the present disclosure, an overview of various elements that may be included in exemplary light-emitting devices of the present disclosure is provided for context. An LED chip typically comprises an active LED structure or region that may have many different semiconductor layers arranged in many different ways. The fabrication and operation of LEDs and their active structures are generally known in the art and are only briefly discussed herein. The layers of the active LED structure may be fabricated using known processes with a suitable process being metal organic chemical vapor deposition. The layers of the active LED structure typically comprise many different layers and generally comprise an active layer sandwiched between n-type and p-type oppositely doped epitaxial layers, all of which are formed successively on a growth substrate. It is understood that additional layers and elements may also be included in the active LED structure, including, but not limited to, buffer layers, nucleation layers, super lattice structures, un-doped layers, cladding layers, contact layers, and current-spreading layers and light extraction layers and elements. The active layer may comprise a single quantum well, a multiple quantum well, a double heterostructure, or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), GaN, GaAs, glass, or silicon. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure may emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories detonated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 750 nm to 1100 nm, or more.

The LED chip may also be covered with one or more lumiphoric or other conversion materials, such as phosphors, such that at least some of the light from the LED chip is absorbed by the one or more phosphors and is converted to one or more different wavelength spectra according to the characteristic emission from the one or more phosphors. In some embodiments, the combination of the LED chip and the one or more phosphors emits a generally white combination of light. The one or more phosphors may include yellow (e.g., YAG:Ce), green (e.g., LuAg:Ce), and red (e.g., Ca_{1-x-y}SrₓEu_{y}AlSiN₃) emitting phosphors, and combinations thereof. Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. In some embodiments, one or more phosphors may include yellow phosphor (e.g., YAG:Ce), green phosphor (e.g., LuAg:Ce), and red phosphor (e.g., Ca_{1-x-y}SrₓEu_{y}AlSiN₃) and combinations thereof. One or more lumiphoric materials may be provided on one or more portions of an LED chip and/or a submount in various configurations.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive”material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are made from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate.

LED packages may include one or more elements, such as lumiphoric materials, encapsulants, light-altering materials, lenses, and electrical contacts, among others, that are provided along with one or more LED chips. In certain aspects, an LED package may include a support member, such as a submount. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. Metal trace patterns may be provided on one or more sides of the submount for receiving and/or electrically connecting with one or more LED chips. Encapsulants may be formed to cover LED chips on submounts to provide protection of underlying LED package elements and sometimes provide light shaping of emissions from LED packages. Encapsulants may include materials that are light-transmissive and/or light-transparent to wavelengths provided of underlying LED chips and/or lumiphoric materials. Suitable encapsulant materials include silicones, plastics, epoxies or glass. In certain aspects, encapsulants may include lens shapes for controlling light emissions.

According to aspects of the present disclosure, light-emitting devices may include multiple LED chips with certain LED package structures, such as submounts and electrical connections, that are joined together by wafer level fabrication. By joining multiple LED chips with a submount that includes electrical connections at the wafer level, individual groups of LED chips that are already bonded to a submount with electrical connections may be singulated to form multiple LED chip light-emitting devices. Wafer level fabrication may include bonding an LED wafer to a submount wafer before various light-emitting devices are singulated. As used herein, an LED wafer may include a growth substrate that has been blanket-deposited with an epitaxial LED structure. Individual LED chips along the growth substrate may be formed by post-epitaxy fabrication that may include removing portions of the epitaxial LED structures along streets to define boundaries of the LED chips. The LED wafer may include other post-epitaxy fabrication, such as formation of reflective structures, anode and cathode electrical contacts for each LED chip, and/or passivation layers, among others. As used herein, a submount wafer may include ceramic materials such as aluminum oxide or alumina, AlN, or organic insulators like PI and PPA, or a PCB, sapphire, Si or any other suitable material. As described below in greater detail, metal trace patterns may be provided on one or more sides of the submount for receiving and/or electrically connecting with one or more LED chips of the LED wafer.

For multiple chip applications, wafer level fabrication provides numerous advantages, including avoiding complex pick and place steps for discrete LED chips where separate die attach steps are provided for each LED chip. In multiple chip applications, increased numbers of separate die attach steps may create increased failures and/or electrical shorting associated with variable bonding strengths and/or variable chip alignments. By bonding at the wafer level, multiple LED chips may be bonded simultaneously to electrical connections of the submount wafer, while spacing between adjacent LED chips is fixed by the LED wafer. According to aspects of the present disclosure, spacings between next-adjacent LED chips in a multiple chip light-emitting device may be provided that are less than or equal to 40 microns (μm), or in a range from 10 μm to 40 μm, or in a range from 20 μm to 40 μm, or in a range from 20 μm to 30 μm after wafer level fabrication. At the wafer level, multiple LED chips may be defined from a common epitaxial structure by forming streets therebetween. In this manner, each LED chip may form a mesa along the LED wafer and the above-described spacing values may be as measured from mesa edge to mesa edge of next adjacent LED chips. Such close spacing may be important in multiple chip light-emitting devices where the multiple LED chips are arranged to collectively provide the appearance of a single light-emitting surface or a single LED chip. In certain embodiments, the substrate on which the LED chips are formed is continuous, thereby also enhancing the appearance of a single LED chip. For example, in flip-chip embodiments where emissions exit through the substrate, having a continuous substrate with no gaps between LED chips may provide the appearance of a single light-emitting surface. It should be understood that the principles described herein are also applicable to applications with larger spacings between LED chips.

Another advantage of wafer level fabrication involves avoiding the need to bin discrete LED chips according to brightness, wavelength, and/or turn-on voltages before assembling in a common device. With wafer level fabrication, next-adjacent LED chips are formed from same areas of a common epitaxial LED structure, thereby eliminating the need to separately bin by brightness, wavelength, and/or turn-on voltages. Yet another advantage of the wafer level fabrication involves the ability to electrically connect the multiple LED chips in different configurations by simply providing different patterns of metal traces on the submount wafer. For example, the submount wafer may include patterns that electrically couple multiple LED chips in series, parallel, series and parallel, and individually addressable configurations. Notably, the wafer level fabrication provides such flexible electrical connections in combination with the above-described close spacings of LED chips. In certain embodiments, a monolithic high voltage chip may be formed by multiple LED chips connected in series or series parallel arrangements, thereby increasing an operating voltage and reducing a step down voltage required for an electrical driver for increased overall system efficiency.

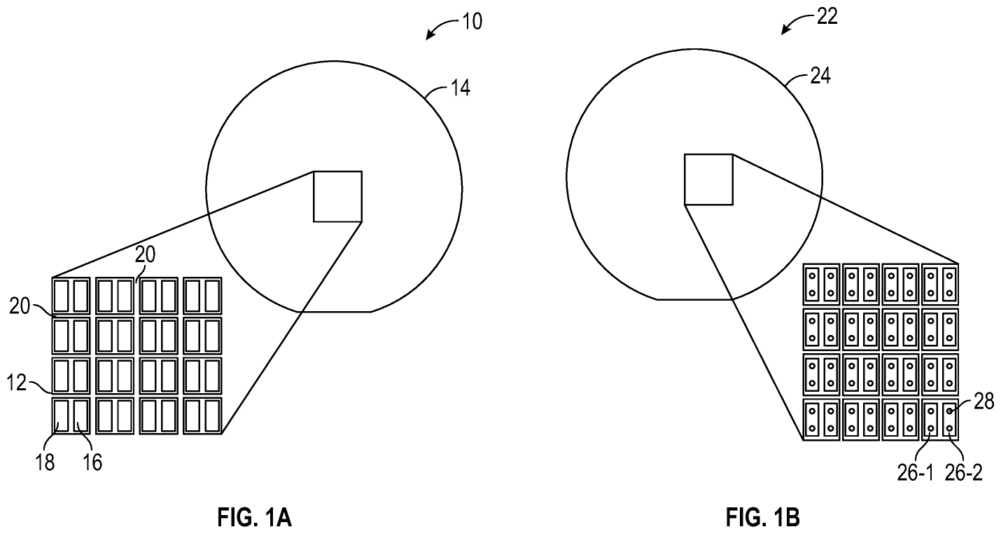

FIG. 1A is top view of an LED wafer 10 with an exploded portion illustrating a view of LED chips 12 formed thereon. The LED wafer 10 includes a substrate structure 14 with a wafer shape. In FIG. 1A, the wafer shape is circular and in other embodiments, the wafer shape may be square or rectangular. The substrate structure 14 may embody a growth wafer, such as sapphire, SiC, AlN, or GaN, among others, on which an epitaxial LED structure as described above may be deposited. Various fabrication steps may define the LED chips 12 from the epitaxial LED structure, including the formation of one or more reflective layers, passivation layers, anode contacts 16, and cathode contacts 18 for each LED chip 12. Streets 20 are formed that define boundaries of each of the LED chips 12. The streets 20 may embody regions where the epitaxial LED structure is removed from the substrate structure 14. In this manner, the streets 20 define the spacings between next-adjacent LED chips 12. As described above, such spacings may be less than or equal to 40 μm, or in a range from 10 μm to 40 μm, or in a range from 20 μm to 40 μm, or in a range from 20 μm to 30 μm in certain embodiments.

FIG. 1B is a top view of a submount wafer 22 with an exploded portion illustrating a view of a first, or frontside, metallization pattern formed thereon. The submount wafer 22 includes a submount structure 24 with a wafer shape. In certain embodiments, the wafer shape of the submount structure 24 corresponds with the wafer shape of the substrate structure 14 of FIG. 1A. The submount structure 24 may comprise any of the material described above and may form a precursor structure that when subdivided, provides a separate submount for multiple light-emitting devices. The first metallization pattern includes a repeating pattern of pairs of a first metal trace 26-1 and a second metal trace 26-2. Each pair of the first metal trace 26-1 and the second metal trace 26-2 are formed with a corresponding shape to the anode contact 16 and the cathode contact 18 of FIG. 1A. In this manner, when the side of the LED wafer 10 visible in FIG. 1A is mounted to side of the submount wafer 22 visible in FIG. 1B, each anode contact 16 may be mechanically bonded to and electrically coupled with a corresponding first metal trace 26-1. In a similar manner, each cathode contact 18 may be mechanically bonded to and electrically coupled with a corresponding second metal trace 26-2. As will be described later in greater detail, one or more vias 28 may be arranged to provide electrically conductive paths through the submount structure 24 to a second metallization pattern that is on an opposing side, or backside, of the submount wafer 22.

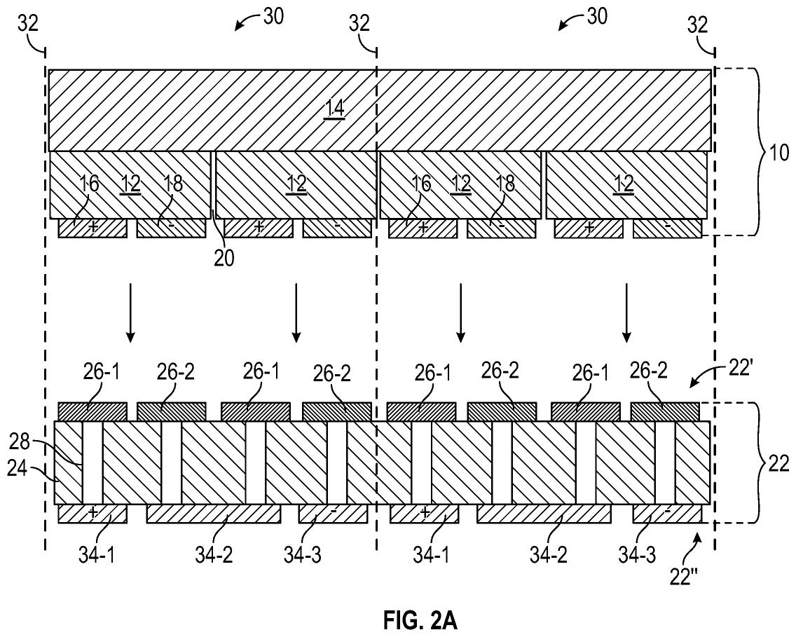

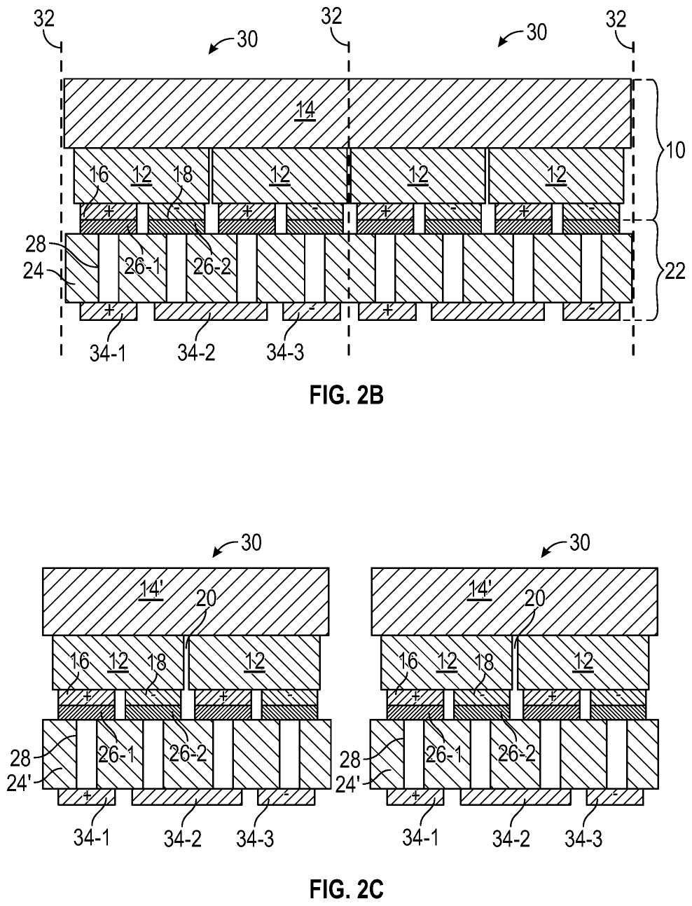

FIG. 2A is a cross-sectional view at a fabrication step for forming multiple light-emitting devices 30 where the LED wafer 10 of FIG. 1A is positioned for mounting to the submount wafer 22 of FIG. 1B. For illustrative purposes, the view provided in FIG. 2A shows only four LED chips 12 with corresponding streets 20, and superimposed vertical dashed lines 32 indicate locations where individual light-emitting devices 30 will later be separated. In practice, the quantity of individual light-emitting devices 30 formed may be much higher, and each individual light-emitting device 30 may include more than two LED chips 12. A wafer aligner may be employed to correctly position the LED wafer 10 relative to the submount wafer 22 so the anode contacts 16 may be aligned with the first metal traces 26-1 and the cathode contacts 18 may be aligned with the second metal traces 26-2.

As illustrated in FIG. 2A, separate vias 28 may be arranged to electrically couple each of the first and second metal traces 26-1, 26-2 of the first metallization pattern on a first side 22′, or frontside, of the submount wafer 22 with a second metallization pattern on a second side 22″, or backside, of the submount wafer 22. The first and second metal traces 26-1, 26-2 may also be referred to as frontside metal traces 26-1, 26-2 herein. The second metallization pattern may be formed by backside metal traces 34-1 to 34-3 that are configured to provide various electrical connections between the LED chips 12. For example, the first and second metal traces 26-1, 26-2 associated with the leftmost LED chip 12 in FIG. 2A are respectively coupled to backside metal traces 34-1, 34-2, while the backside metal trace 34-2 is also electrically coupled to the first metal trace 26-1 associated with the next adjacent LED chip 12. Finally, the second metal trace 26-2 associated with the next adjacent LED chip 12 is electrically coupled with the backside metal trace 34-3. In this manner, the LED chips 12 of each light-emitting device 30 may be electrically coupled in series based on the arrangement of the submount wafer 22.

FIG. 2B is a cross-sectional view at a subsequent fabrication step to FIG. 2A where the LED wafer 10 is bonded to the submount wafer 22. As illustrated, corresponding pairs of the anode contacts 16 and cathode contacts 18 are bonded to corresponding pairs of the frontside metal traces 26-1, 26-2. Such wafer bonding may be provided by various techniques that mechanically and electrically bond metals of each anode contact 16 and each cathode contact 18 with metals of corresponding frontside metal traces 26-1, 26-2. For example, bonding may include thermocompression bonding of certain same metals, such as gold (Au), copper (Cu), or aluminum (Al), among others, that are present at interfaces formed between the anode or cathode contacts 16, 18, and the corresponding frontside metal trace 26-1, 26-2. Other bonding may involve die attach metal stacks formed at the interfaces, such as eutectic metal stacks including gold-tin (Au—Sn), gold-silicon (Au—Si), gold-germanium (Au—Ge), aluminum-germanium (Al—Ge), or gold-indium (Au—In), among others. Still further bonding may involve transient liquid phase bonding with copper-tin (Cu—Sn), Au—In, or silver-tin (Ag—Sn), among others. Additional bonding may involve bump bonding by way of a pattern of solder bumps or by way of solder paste bonding.

FIG. 2C is a cross-sectional view at a subsequent fabrication step to FIG. 2B where the light-emitting devices 30 have been separated from one another along the vertical dashed lines 32 of FIG. 2B. Separation may be accomplished by way of wafer dicing or singulation, such as mechanical sawing or laser dicing among others. After separation, each light-emitting device 30 includes a substrate 14′ separated from the substrate structure 14 of FIG. 2B and a submount 24′ separated from the submount structure 24 of FIG. 2B. Each of the light-emitting devices 30 may embody multiple chip devices where arrays of the LED chips 12 are closely spaced and formed from common regions of an epitaxial LED structure. The spacing may be determined by the streets 20 as previously described. The light-emitting devices 30 may be well suited to be arranged within LED packages or within larger LED lighting systems. In certain embodiments, the substrates 14′ may comprise materials, such as sapphire, that are light-transmissive or light-transparent to wavelengths generated by the LED chips 12. In other embodiments, the substrates 14′ may not be required. For example, the substrate structure 14 of FIG. 2B may be removed after bonding to the submount wafer 22 such that the light-emitting devices 30 of FIG. 2C may not include the substrates 14′.

After singulation, the backside metal traces 34-1 and 34-3 of each light-emitting device 30 form anode and cathode mounting pads for mounting to external electrical connections, with the other backside metal traces 34-2 forming a part of electrically conductive paths therebetween. For example, the electrically conductive path between the backside metal traces 34-1 and 34-3 is routed through the submount 24′ by way of the via 28, through the left LED chip 12, back through the submount 24′ to the backside metal trace 34-2, back through the submount 24′ to the next LED chip 12, and finally back through the submount 24′ to the backside metal trace 34-3.

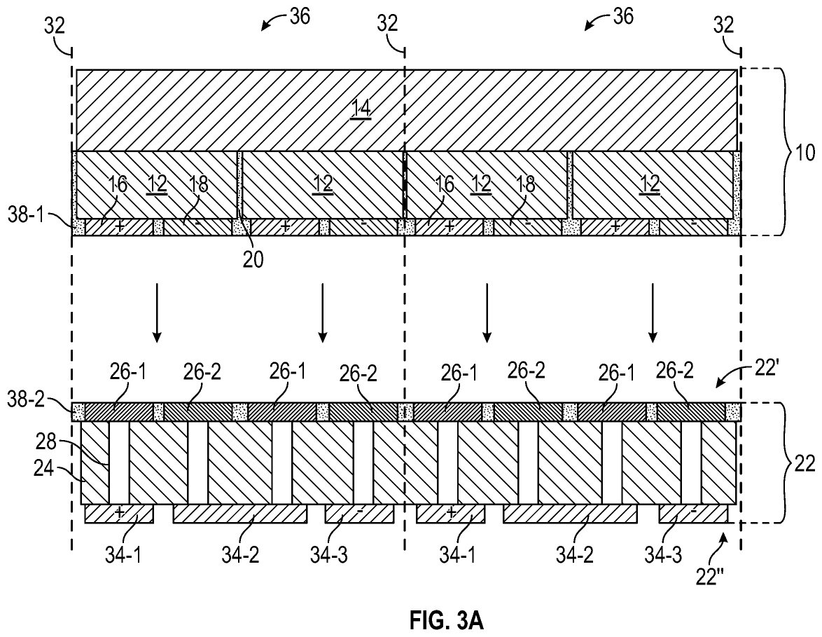

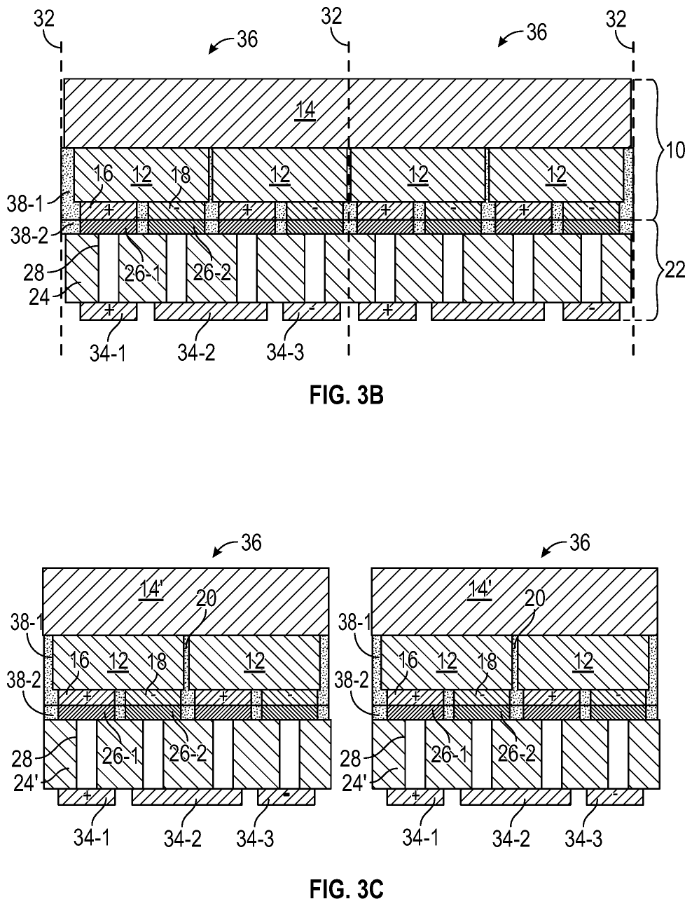

FIGS. 3A-3C illustrated cross-sectional views at fabrication steps for forming multiple light-emitting devices 36 that are similar to the light-emitting devices 30 of FIGS. 2A-2C and further include one or more underfill materials 38-1, 38-2. In this manner, the description of fabrication steps for FIGS. 2A-2C is readily applicable to the fabrication steps for FIGS. 3A-3C along with further details provided below.

FIG. 3A is a cross-sectional view at a fabrication step for forming multiple light-emitting devices 36 that is similar to the fabrication step illustrated in FIG. 2A. In FIG. 3A, a first underfill material 38-1 may be formed on the LED wafer 10 to fill in the streets 20 and other topography variations associated with the LED chips 12, anode contacts 16, and/or cathode contacts 18. The first underfill material 38-1 may initially be formed to entirely cover the LED chips 12, the anode contacts 16, and the cathode contacts 18, before a removal step is employed to expose surfaces of the anode contacts 16 and the cathode contacts 18. The removal step may include grinding and or polishing the first underfill material 38-1 to effectively planarize it with the anode contacts 16 and the cathode contacts 18. In certain embodiments, the first underfill material 38-1 may be coplanar with the exposes surfaces of the anode contacts 16 and the cathode contacts 18. The first underfill material 38-1 may include light-altering and/or light-reflective materials that are configured to redirect downward propagating light from the LED chips 12 for increased brightness. In certain embodiments, the first underfill material 38-1 may be formed by smearing, dispensing with partial or full curing, or spin-coating, among others. The first underfill material 38-1 may include ceramic materials that enhance bonding, such as ceramic pastes, spin-on-dielectrics, and/or sol gel reactions (e.g., inorganic colloidal suspension and gelation in a continuous liquid phase). A second underfill material 38-2 may be formed on the submount wafer 22 in a similar manner and with similar materials as the first underfill material 38-1. In this manner, the second underfill material 38-2 may cover topography variations associated with the frontside metal traces 26-1, 26-2 or other features that may be present on the first side 22′. In other embodiments, the second underfill material 38-2 may be omitted.

FIG. 3B is a cross-sectional view at a subsequent fabrication step to FIG. 3A for forming the multiple light-emitting devices 36 that is similar to the fabrication step illustrated in FIG. 2B. As such, the LED wafer 10 is bonded to the submount wafer 22 as described above. As illustrated, the presence of the first and second underfill materials 38-1, 38-2 may effectively fill gaps between the submount wafer 22 and the LED wafer 10. In this manner, improved thermal contact area may be provided. For embodiments where the first and second underfill materials 38-1, 38-2 comprise ceramic materials as described above, the ceramic materials may form ceramic bonds therebetween that improve mechanical integrity with enhanced heat conduction for the light-emitting devices 36. In certain embodiments, the first and second underfill materials 38-1, 38-2 may not be formed prior to wafer bonding. Rather, the first and second underfill materials 38-1, 38-2 may be applied to fill spaces between the LED wafer 10 and the submount wafer 22 after bonding. For example, the underfill materials 38-1, 38-2 may be applied with suitable viscosity to effectively wick and fill the spaces between the LED wafer 10 and the submount wafer 22 before curing. In such embodiments, the first and second underfill materials 38-1, 38-2 may embody a single continuous layer.

FIG. 3C is a cross-sectional view at a subsequent fabrication step to FIG. 3B for forming the multiple light-emitting devices 36 that is similar to the fabrication step illustrated in FIG. 2C. In this regard, individual light-emitting devices 36 may be formed with the first and second underfill materials 38-1, 38-2 formed between the substrates 14′ and the submounts 24′. As with FIG. 2C, the substrates 14′ may be optional in certain embodiments.

The configuration of frontside and backside metal traces of the submount wafer described above may be well suited for providing different electrical arrangements of wafer-bonded LED chips. The principles described may be applied to multiple chip light-emitting devices with electrical configurations of LED chips coupled in series, parallel, series and parallel combinations, and individually addressable configurations. In certain aspects, a submount wafer may be formed with different patterns of backside metal traces in different locations such that after wafer bonding with an LED wafer and subsequent singulation, some light-emitting devices may be formed with a first electrical configuration and other light-emitting devices from the same LED wafer may be formed with a second electrical configuration that is different from the first electrical configuration. Accordingly, many different types of light-emitting devices may be fabricated simultaneously by simply providing various backside metallization patterns along the submount wafer.

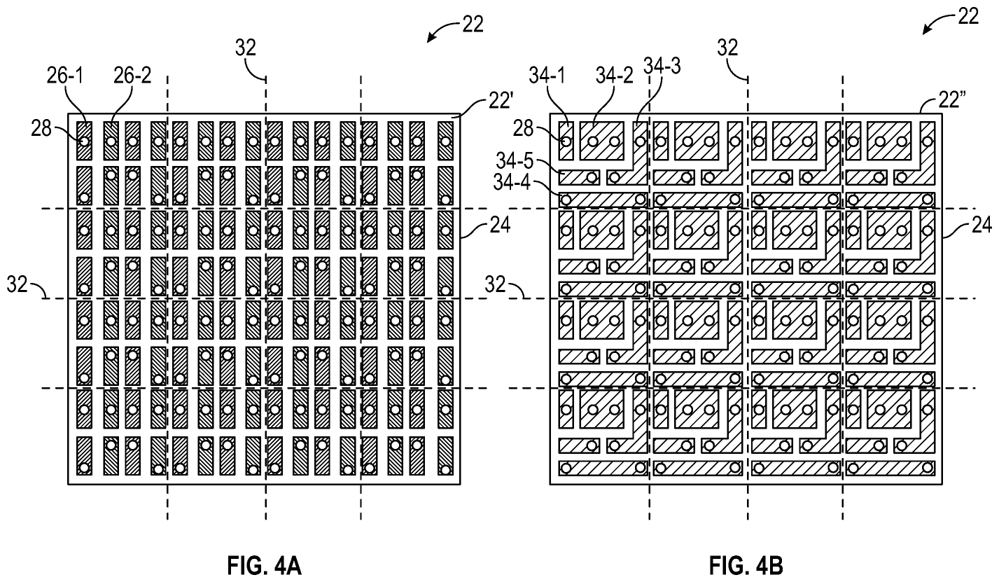

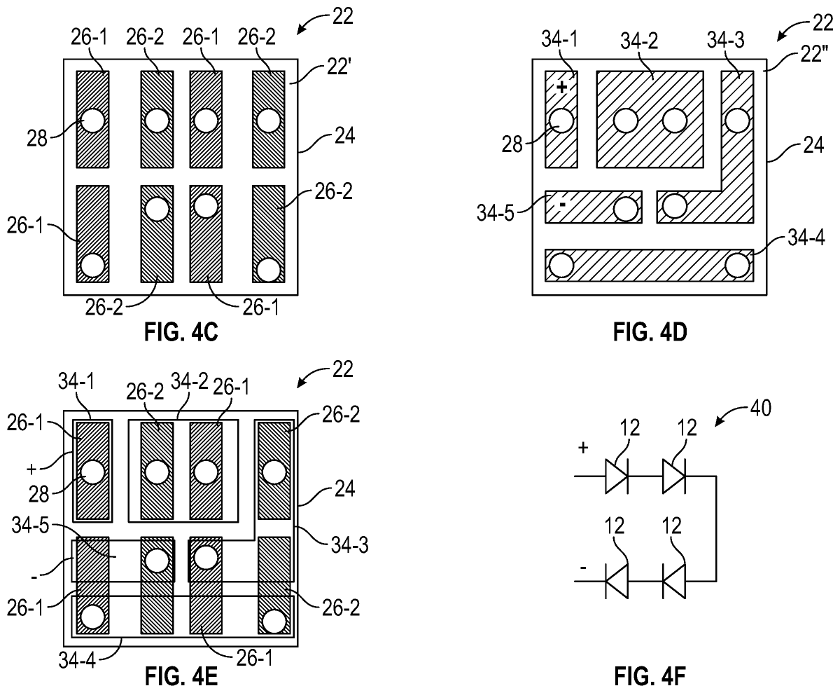

FIGS. 4A and 4B illustrate larger portions of the submount wafer 22 described above for FIGS. 1B to 3C that provide serial connections between LED chips of corresponding light-emitting devices. FIG. 4A is a view of the first side 22′ of the submount wafer 22 where superimposed vertical and horizontal dashed lines 32 form a grid of sixteen different device regions, each of which includes four pairs of the frontside metal traces 26-1, 26-2. As described above, the frontside metal traces 26-1, 26-2 are configured to be bonded to anode and cathode contacts 16, 18 of the LED chips 12 as illustrated, for example, in FIGS. 2A to 2C. For illustrative purposes, FIG. 4B is a view of the submount wafer 22 from the same orientation as FIG. 4A, except with the frontside metal traces 26-1, 26-2 removed and the submount structure 24 illustrated as transparent. The locations of the vias 28 remain illustrated. In this manner, locations of backside metal traces 34-1 to 34-5 are provided with an alignment that corresponds with FIG. 4A. Accordingly, the illustration of FIG. 4A may be overlaid with the illustration of FIG. 4B without rotation.

FIGS. 4C to 4E illustrate portions of the submount wafer 22 from one of the device regions of FIGS. 4A and 4B. FIG. 4C is a view of a portion of FIG. 4A and illustrates four pairs of the frontside metal traces 26-1, 26-2 for a single device region. In this manner, four LED chips may be flip-chip mounted to the pairs of frontside metal traces 26-1, 26-2. FIG. 4D is a view from a portion FIG. 4B and illustrates the backside metal traces 34-1 to 34-5 along with the locations of the vias 28. The backside metal traces 34-1, 34-5 form anode and cathode mounting pads for mounting to external electrical connections, with the other backside metal traces 34-2, 34-3 and 34-4 forming parts of interconnection paths therebetween. To accommodate various interconnection paths, certain ones of the backside metal traces (e.g., 34-2, 34-3, 34-5) that are intended to electrically couple different LED chips together may have different shapes from one another, such as wider shapes (e.g., 34-2), nonlinear shapes (e.g., 34-3), and/or longer shapes (e.g., 34-4). While the portion of the submount structure 24 in FIG. 4C is illustrated as square, other shapes, such as rectangles may be provided by adjusting positions of separation lines corresponding to the dashed lines 32 of FIGS. 4A and 4B.

FIG. 4E is a view of the submount wafer 22 where the image of FIG. 4C with the frontside metal traces 26-1, 26-2 is overlaid on the image of FIG. 4D with alignment according to the vias 28. The vias 28 define locations where certain ones of the frontside metal traces 26-1, 26-2 are electrically coupled with corresponding ones of the backside metal traces 34-1 to 34-5 through the submount structure 24. FIG. 4F illustrates an equivalent circuit 40 for LED chips 12 that may be subsequently mounted to the frontside metal traces 26-1, 26-2 on the first side 22′. As illustrated, the arrangement of the vias 28 and the backside metal traces 34-1 to 34-5 provides a serial arrangement for LED chips that may be employed for high voltage applications.

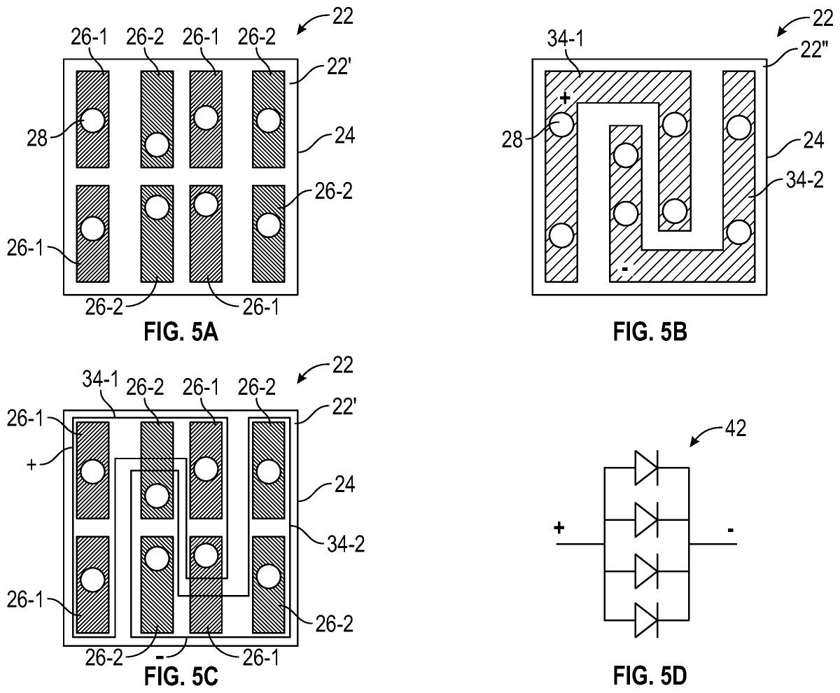

FIGS. 5A to 5D illustrates an additional configuration of the submount wafer 22 of FIGS. 4A to 4D that provide parallel connections for corresponding light-emitting devices. FIG. 5A is a view of the first side 22′ of the submount wafer 22 that is similar to FIG. 4C, except locations of one or more of the vias 28 relative to each of the frontside metal traces 26-1, 26-2 are different to accommodate parallel coupling as described below. FIG. 5B is a view of the backside 22″ of the submount wafer 22 from FIG. 5A. As illustrated, only two backside metal traces 34-1, 34-2 are arranged relative to the vias 28, the backside metal trace 34-1 forms the anode mounting pad, and the backside metal trace 34-2 forms the cathode mounting pad. FIG. 5C is a view of the submount wafer 22 where the image of FIG. 5A with the frontside metal traces 26-1, 26-2 is overlaid on the image of FIG. 5B with alignment according to the vias 28. The vias 28 define locations where certain ones of the frontside metal traces 26-1, 26-2 are electrically coupled with corresponding ones of the backside metal traces 34-1, 34-2 through the submount structure 24. As illustrated, each frontside metal trace 26-1 is electrically coupled to the backside metal trace 34-1 while each frontside metal trace 26-2 is electrically coupled to the backside metal trace 34-2. FIG. 5D illustrates an equivalent circuit 42 for LED chips 12 that may be subsequently mounted to the frontside metal traces 26-1, 26-2 on the first side 22′. As illustrated, the arrangement of the vias 28 and the backside metal traces 34-1, 34-2 provides a parallel arrangement for the LED chips 12. In certain embodiments, a single submount wafer 22 may include one or more regions configured to provide parallel connections for light-emitting devices as illustrated in FIGS. 5A to 5D and one or more other regions configured to provide serial connections for light-emitting devices as illustrated in FIGS. 4A to 4F.

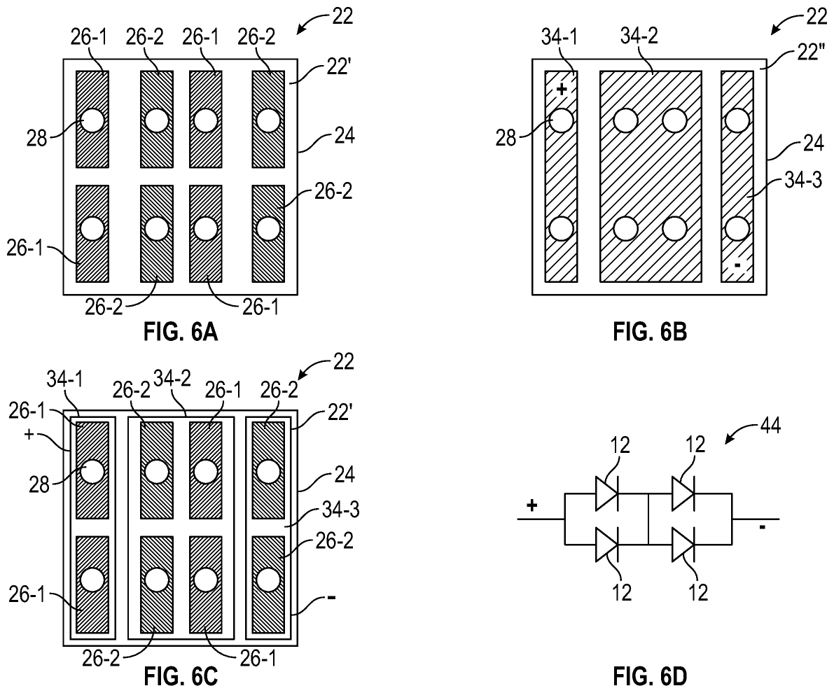

FIGS. 6A to 6D illustrates another additional configuration of the submount wafer 22 of FIGS. 4A to 4D that provide parallel and series connections for corresponding light-emitting devices. FIG. 6A is a view of the first side 22′ of the submount wafer 22 that is similar to FIG. 4C, except locations of one or more of the vias 28 relative to each of the frontside metal traces 26-1, 26-2 are different to accommodate parallel and series coupling as described below. FIG. 6B is a view of the backside 22″ of the submount wafer 22 from FIG. 6A. As illustrated, only three backside metal traces 34-1 to 34-3 are arranged relative to the vias 28, the backside metal traces 34-1, 34-3 form anode and cathode mounting pads, and the backside metal trace 34-2 forms part of an electrical interconnection therebetween. FIG. 6C is a view of the submount wafer 22 where the image of FIG. 6A with the frontside metal traces 26-1, 26-2 is overlaid on the image of FIG. 6B with alignment according to the vias 28. The vias 28 define locations where certain ones of the frontside metal traces 26-1, 26-2 are electrically coupled with corresponding ones of the backside metal traces 34-1 to 34-3 through the submount structure 24. FIG. 6D illustrates an equivalent circuit 44 for LED chips 12 that may be subsequently mounted to the frontside metal traces 26-1, 26-2 on the first side 22′. As illustrated, the arrangement of the vias 28 and the backside metal traces 34-1 to 34-3 provides a parallel and series arrangement for the LED chips 12. In certain embodiments, a single submount wafer 22 may include one or more regions configured to provide parallel connections for light-emitting devices as illustrated in FIGS. 6A to 6D and one or more other regions configured to provide serial connections for light-emitting devices as illustrated in FIGS. 4A to 4F. In still further embodiments, a single submount wafer 22 may include different regions according to each of FIGS. 4A to 4F, FIGS. 5A to 5D, and FIGS. 6A to 6D.

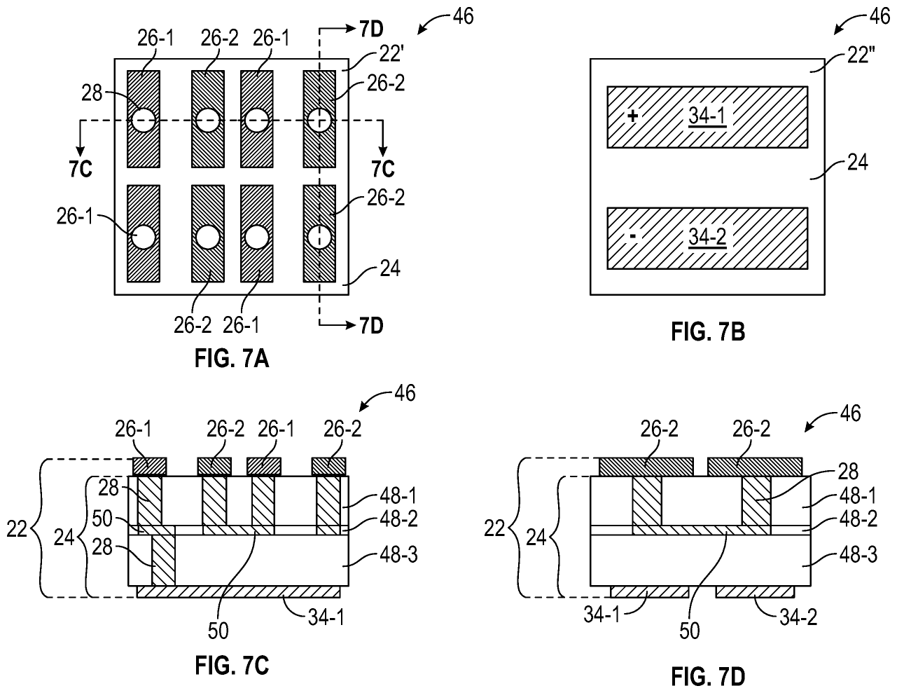

FIGS. 7A to 7D illustrate an alternative configuration for a submount wafer 46 that includes a multiple layer structure with vias and interconnections that rout electrically conductive paths between frontside metal traces 26-1, 26-2 and backside metal traces 34-1, 34-2. Multiple layer arrangements for the submount structure 24 may include multiple sublayers 48-1 to 48-3 that provide increased flexibility in routing electrical connections. In certain embodiments, the sublayers 48-1 to 48-3 may include a laminate structure with vias 28 and interconnections 50 formed therein. The laminate structure may include multiple layer ceramic structures, such as multiple layer printed circuit boards.

FIG. 7A is a frontside view of a portion of the submount wafer 46 that is similar to the view provided by FIG. 4C. Accordingly, four pairs of the frontside metal traces 26-1, 26-2 for a single device region are illustrated. However, as with previous embodiments, any number of pairs of frontside metal traces 26-1, 26-2 may be provided depending on a number of LED chips intended for each light-emitting device. FIG. 7B is a backside view of the submount wafer 46 of FIG. 7A, illustrating two backside metal traces 34-1, 34-2 that form anode and cathode mounting pads for the corresponding light-emitting device. Despite only have two backside metal traces 34-1, 34-2, any number of serial, parallel, and series and parallel arrangements may be provided by the multiple layer configuration of the submount structure 24. FIG. 7C is a cross-section taken along the sectional line 7C-7C of FIG. 7A, and FIG. 7D is a cross-section taken along the sectional line 7D-7D of FIG. 7A. As illustrated, the frontside traces 26-1, 26-2 may be formed on the sublayer 48-1 and a number of vias 28 may extend through the sublayer 48-1 from each of the frontside traces 26-1, 26-2. Interconnections 50 may be arranged within the next sublayer 48-2 that redirect electrically conductive paths horizontally within the submount structure 24. In the cross-section of FIG. 7C, another via 28 is arranged within the next sublayer 48-3 that provides an electrically conductive path to the backside metal trace 34-1. Electrically conductive paths to the other backside metal trace 34-2 may be arranged in other locations outside of the cross-sections of FIGS. 7C and 7D.

As described above, the multiple layer structure may provide increased design flexibility for the submount wafer 46. For example, the backside metal traces 34-1, 34-2 may form a single anode and a single cathode with a pattern that is not necessarily tied to locations of each of the vias 28 as illustrated in FIG. 7B. Accordingly, other areas of the backside are open to include other features, such as a neutral thermal pad for heat dissipation purposes. In further embodiments, the multiple layer structure allows additional anode and cathode contacts to provide individual addressability for LED chips. Various shapes for light-emitting devices may be formed from submount wafers with multiple layer structures, such as squares and rectangles, among others.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method comprising:
providing a light-emitting diode (LED) wafer comprising a plurality of LED chips, each LED chip of the plurality of LED chips comprising an anode contact and a cathode contact;
providing a submount wafer comprising a first metallization pattern on a frontside of the submount wafer and a second metallization pattern on a backside of the submount wafer, the second metallization pattern being electrically coupled to the first metallization pattern;
bonding the LED wafer to the frontside of the submount wafer such that the anode contact and the cathode contact of each LED chip are electrically coupled to the first metallization pattern; and
singulating the LED wafer and the submount wafer to form a plurality of light-emitting devices, each light-emitting device of the plurality of light-emitting devices comprising a substrate formed from the LED wafer, an array of LED chips of the plurality of LED chips, and a submount formed from the submount wafer.

2. The method of claim 1, wherein the LED wafer comprises a substrate structure that is subdivided to form each substrate of the plurality of light-emitting devices, and the submount wafer comprises a submount structure that is subdivided to form each submount of the plurality of light-emitting devices.

3. The method of claim 2, wherein the substrate structure comprises a sapphire wafer on which the plurality of LED chips are formed.

4. The method of claim 2, wherein the submount structure comprises aluminum oxide or aluminum nitride.

5. The method of claim 1, wherein the first metallization pattern comprises a separate pair of an anode metal trace and a cathode metal trace that are respectively bonded to the anode contact and the cathode contact of each LED chip of the plurality of LED chips.

6. The method of claim 5, wherein the second metallization pattern comprises a first metal trace that forms an anode mounting pad, a second metal trace that forms a cathode mounting pad, and a third metal trace that forms part of an electrically conductive path between the first metal trace and the second metal trace.

7. The method of claim 1, wherein a spacing between next adjacent LED chips of the plurality of LED chips is less than or equal to 40 microns (μm).

8. The method of claim 7, wherein the spacing is in a range from 10 μm to 40 μm.

9. The method of claim 1, wherein the plurality of LED chips are subdivided from a common epitaxial LED structure.

10. The method of claim 1, wherein bonding the LED wafer to the frontside of the submount wafer comprises thermocompression bonding, eutectic bonding, transient liquid phase bonding, bump bonding, or solder paste bonding the anode contact and the cathode contact to the first metallization pattern.

11. The method of claim 1, wherein bonding the LED wafer to the frontside of the submount wafer comprises forming a ceramic bond between the LED wafer and the submount wafer.

12. The method of claim 1, further comprising forming an underfill material in gaps between the LED wafer and the submount wafer.

13. The method of claim 1, wherein the array of LED chips are electrically coupled in series, in parallel, or in series and parallel.

14. The method of claim 1, wherein the second metallization pattern comprises:
a first pattern of metal traces configured to electrically couple the array of LED chips for a first light-emitting device of the plurality of light-emitting devices with a first electrical configuration; and
a second pattern of metal traces configured to electrically couple the array of LED chips for a second light-emitting device of the plurality of light-emitting devices with a second electrical configuration.

15. The method of claim 1, wherein the submount structure comprises a multiple layer ceramic structure.

16. A method comprising:
providing a light-emitting diode (LED) wafer comprising a plurality of LED chips on a substrate structure;
forming a first underfill material on the LED wafer;
providing a submount wafer comprising a first metallization pattern on a frontside of the submount wafer and a second metallization pattern on a backside of the submount wafer, the second metallization pattern being electrically coupled to the first metallization pattern;
bonding the LED wafer to the frontside of the submount wafer such that the plurality of LED chips are electrically coupled to the first metallization pattern; and
singulating the LED wafer and the submount wafer to form a plurality of light-emitting devices, each light-emitting device of the plurality of light-emitting devices comprising an array of LED chips of the plurality of LED chips and a submount formed from the submount wafer.

17. The method of claim 16, wherein the LED wafer comprises a plurality of streets that define boundaries of each LED chip of the plurality of LED chips and the first underfill material is arranged to fill portions of the plurality of streets.

18. The method of claim 16, wherein the first underfill material comprises light-reflective materials configured to reflect or redirect light from the plurality of LED chips.

19. The method of claim 16, wherein the first underfill material is formed on the LED wafer after the LED wafer is mounted to the submount wafer.

20. The method of claim 16, wherein the first underfill material is formed on the LED wafer before the LED wafer is mounted to the submount wafer.

21. The method of claim 20, further comprising forming a second underfill material on the submount wafer before the LED wafer is mounted to the submount wafer.

22. The method of claim 21, wherein the first underfill material and the second underfill material form a ceramic bond between the LED wafer and the submount wafer.

23. The method of claim 16, wherein the array of LED chips are electrically coupled in series, in parallel, or in series and parallel.
